(19) United States
(12) Patent Application Publication
(10) Pub. No.: US 2025/0253767 A1
(43) Pub. Date: Aug. 7, 2025

(54) POWER MODULE WITH PASSIVE COMPONENT LAYER

(71) Applicant: Monolithic Power Systems, Inc., Kirkland, WA (US)

(72) Inventors: Ting GE, San Jose, CA (US); Yingjiang PU, Chengdu (CN); Yingxin ZHOU, Hangzhou (CN)

(21) Appl. No.: 19/187,807

(22) Filed: Apr. 23, 2025

Related U.S. Application Data
(63) Continuation-in-part of application No. 18/830,167, filed on Sep. 10, 2024.
Application No. 18/830,167 is a continuation-in-part of application No. 17/870,555, filed on Jul. 21, 2022, now Pat. No. 12,120,822.
Application No. 17/870,555 is a continuation-in-part of application No. 17/678,172, filed on Feb. 23, 2022, now Pat. No. 12,095,369.

(51) Int. Cl. H02M 3/00; H02M 3/158; H05K 1/14; H05K 1/18

(52) U.S. Cl. CPC H02M 3/003; H05K 1/144; H05K 1/181; H05K 1/182; H02M 3/1584; H05K 2201/10015; H05K 2201/1003

(57) ABSTRACT

A power module comprises an active layer and a passive component layer. The active layer has a first substrate and a first pair of switches. The passive component layer has a second substrate, an input capacitor and a magnetic device. The input capacitor and the magnetic device are attached between a bottom surface of the first substrate and a top surface of the second substrate. The magnetic device comprises a first turn having a first end that is connected to a first switch node formed by the first pair of switches. The input capacitor has a first conducting terminal and a second conducting terminal, at least one of the first conducting terminal and the second conducting terminal is extended between the bottom surface of the first substrate and the top surface of the second substrate to provide electrical connection between the second substrate and the first substrate.

### CROSS-REFERENCE TO RELATED APPLICATIONS

The present application is a continuation-in-part of U.S. application Ser. No. 18/830,167, filed on Sep. 10, 2024, which is a continuation-in-part of U.S. application Ser. No. 17/870,555, filed on Jul. 21, 2022, which is a continuation-in-part of U.S. application Ser. No. 17/678,172, filed on Feb. 23, 2022. All of these related applications are incorporated herein by reference in their entirety.

### BACKGROUND OF THE INVENTION

### 1. Field of the Invention

The present invention generally relates to electrical circuits, and more particularly but not exclusively relates to power modules.

### 2. Description of Related Art

A power module comprises power converters that are implemented on a substrate, such as a printed circuit board (PCB). Power modules may be employed to provide one or more supply voltages to various electrical devices. A power module may provide two or more output phases by incorporating a corresponding number of power converters, with each power converter providing a phase of the output. Embodiments of the present invention pertain to power modules with a low profile, allowing them to be used in automotive, computer server, and other applications where space is a premium.

### SUMMARY OF THE INVENTION

In one embodiment, a power module comprises an active layer and a passive component layer. The active layer has a first substrate and a first pair of switches. The passive component layer has a second substrate, an input capacitor and a magnetic device. The input capacitor and the magnetic device are attached between a bottom surface of the first substrate and a top surface of the second substrate which faces toward the bottom surface of the first substrate. The magnetic device comprises a first turn having a first end that is connected to a first switch node formed by the first pair of switches. The input capacitor has a first conducting terminal and a second conducting terminal, at least one of the first conducting terminal and the second conducting terminal is extended between the bottom surface of the first substrate and the top surface of the second substrate to provide electrical connection between the second substrate and the first substrate.

In another embodiment, a power module comprises a first substrate, a second substrate disposed beneath the first substrate, a first integrated circuit (IC) die and a second IC die, at least one capacitor and a magnetic device attached between a bottom surface of the first substrate and a top surface of the second substrate. The first IC die has a first pair of switches and a second pair of switches, the second IC die has a third pair of switches and a fourth pair of switches. The at least one capacitor has a first conducting terminal and a second conducting terminal as vias to provide electrical connections between the second substrate and the first substrate respectively. The magnetic device comprises a first turn, a second turn, a third turn, and a fourth turn. The first end of the first turn is connected to a first switch node formed by the first pair of switches, a first end of the second turn is connected to a second switch node formed by the second pair of switches, a first end of the third turn is connected to a third switch node formed by the third pair of switches, and a first end of the fourth turn is connected to a fourth switch node formed by the fourth pair of switches.

In yet another embodiment, a power supply system comprises a motherboard having a first side and a second side, and a power module. A load is mounted on the first side of the motherboard. The power module is attached to the second side of the motherboard. the power module comprises an active layer having a first pair of switches and a passive component layer having a substrate, at least one capacitor and a magnetic device. The capacitor and the magnetic device are attached between a bottom surface of the active layer and a top surface of the substrate, the at least one capacitor has a first conducting terminal and a second conducting terminal as vias to provide electrical connections between the substrate and the active layer respectively.

These and other features of the present disclosure will be readily apparent to persons of ordinary skill in the art upon reading the entirety of this disclosure, which includes the accompanying drawings and claims.

### BRIEF DESCRIPTION OF DRAWINGS

The present invention can be further understood with reference to the following detailed description and the appended drawings, wherein like elements are provided with like reference numerals. These drawings are only for illustration purpose, thus may only show part of the devices and are not necessarily drawn to scale.

FIG. 1 shows a schematic diagram of a power module 100 in accordance with an embodiment of the present invention.

FIG. 2 shows a top view, a bottom view, and a side view of a physical layout of the power module 100 of FIG. 1 in accordance with an embodiment of the present invention.

FIG. 3 shows a cross-sectional view of a substrate of the power module 100 of FIG. 2 in accordance with an embodiment of the present invention.

FIG. 4 shows a top view of a physical layout of a power module in accordance with an embodiment of the present invention.

FIG. 5 shows a side view of the power module of FIG. 4 in accordance with an embodiment of the present invention.

FIG. 6 shows a cross-sectional view of the power module of FIG. 4 in accordance with an embodiment of the present invention.

FIG. 7 shows a top surface of an output capacitor substrate layer in accordance with an embodiment of the present invention.

FIG. 8 shows a side view of a power module 500 in accordance with an embodiment of the present invention.

FIG. 9 shows a side cross-sectional view of the power module of FIG. 8 in accordance with an embodiment of the present invention.

FIG. 10A shows a side cross-sectional view of a power module 600A in accordance with an embodiment of the present invention.

FIG. 10B shows a side cross-sectional view of a power module 600B in accordance with an embodiment of the present invention.

FIG. 10C shows a three-dimensional (3D) view of a capacitor 63 in accordance with an embodiment of the present invention.

FIG. 10D shows a 3D transparent view of the capacitor 63 in accordance with another embodiment of the present invention.

FIG. 10E shows a 3D transparent view of the capacitor 63 in accordance with yet another embodiment of the present invention.

FIG. 11 shows a three-dimensional (3D) transparent view of a power module 700 in accordance with an embodiment of the present invention.

FIG. 12 shows a top view of a physical layout of a substrate 621 of the power module 700 in accordance with an embodiment of the present invention.

FIG. 13 shows a top view of a physical layout of a substrate 611 of the power module 700 in accordance with an embodiment of the present invention.

FIG. 14 shows a bottom view of the power module 700 in accordance with an embodiment of the present invention.

FIG. 15 shows a side cross-sectional view of the power module 700 of FIG. 13 in accordance with an embodiment of the present invention.

FIG. 16 shows a side cross-sectional view of the power module 700 of FIG. 13 in accordance with another embodiment of the present invention.

FIG. 17 shows a 3D transparent view of a magnetic device 612-1 in accordance with an embodiment of the present invention.

FIG. 18 shows a top view of a top surface 6121 of the magnetic device 612-1 of FIG. 17 in accordance with an embodiment of the present invention.

FIG. 19 shows a bottom view of a bottom surface 6122 of the magnetic device 612-1 of FIG. 17 in accordance with an embodiment of the present invention.

FIG. 20 shows a 3D transparent view of a magnetic device 612-1B in accordance with an embodiment of the present invention.

FIG. 21 shows a top view of a top surface 6121B of the magnetic device 612-1B of FIG. 20 in accordance with an embodiment of the present invention.

FIG. 22 shows a bottom view of a bottom surface 6122B of the magnetic device 612-1B of FIG. 20 in accordance with an embodiment of the present invention.

FIG. 23 shows a top view of a physical layout of the substrate 611 of the power module 700 in accordance with another embodiment of the present invention.

FIG. 24 shows a 3D transparent view of a magnetic device 612 in accordance with an embodiment of the present invention.

FIG. 25 shows a side cross-sectional view of a power module 800 in accordance with an embodiment of the present invention.

FIG. 26 shows a bottom view of a physical layout of the substrate 621 of the power module 800 in accordance with an embodiment of the present invention.

FIG. 27 shows a top view of a physical layout of the substrate 611 of the power module 800 in accordance with an embodiment of the present invention.

FIG. 28 shows a side view of a physical layout of a power supply system 900 in accordance with an embodiment of the present invention.

### DETAILED DESCRIPTION OF THE INVENTION

In the present disclosure, numerous specific details are provided, such as examples of electrical circuits and components, to provide a thorough understanding of embodiments of the invention. Persons of ordinary skill in the art will recognize, however, that the invention can be practiced without one or more of the specific details. It is noted that, for purposes of illustrative clarity, certain elements in the drawings may not be drawn to scale. In other instances, well-known details are not shown or described to avoid obscuring aspects of the invention.

Throughout the specification and claims, the terms “left”,” right “, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

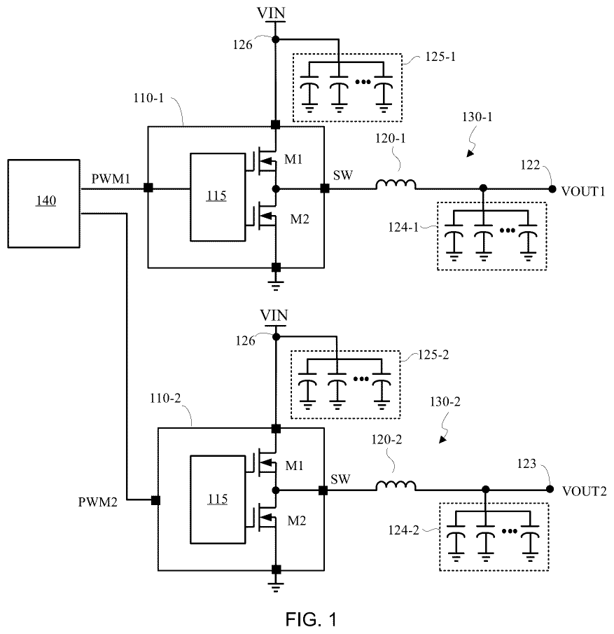

FIG. 1 shows a schematic diagram of a power module 100 in accordance with an embodiment of the present invention. In the example of FIG. 1, the power module 100 has two power converters 130 (i.e., 130-1, 130-2), with each power converter 130 comprising an output inductor 120 (i.e., 120-1, 120-2), an input capacitor 125 (i.e., 125-1, 125-2), an output capacitor 124 (i.e., 124-1, 124-2), and a monolithic integrated circuit (IC) switch block 110 (i.e., 110-1, 110-2). In one embodiment, each input capacitor 125 comprises a plurality of discrete capacitors that are connected in parallel between an input voltage node 126 and a power ground, each output capacitor 124 comprises a plurality of discrete capacitors that are connected in parallel between an output voltage node (e.g., 122, 123) and the power ground. In the example of FIG. 1, a power converter 130 is a buck converter. As can be appreciated, a power converter 130 may also be configured as a boost converter or other type of power converter depending on the application.

Each of the power converters 130-1 and 130-2 receives an input voltage VIN at the input voltage node 126 and generates an output voltage VOUT (i.e., VOUT1 at the output voltage node 122, VOUT2 at the output voltage node 123). The output voltages of the power converters 130-1 and 130-2 may be connected together and interleaved to generate a multiphase output voltage. For example, an output voltage node 122 and an output voltage node 123 may be connected together to provide the output voltage VOUT, with each power converter 130 providing a phase of a multiphase output voltage. In that example, the power module 100 may include additional power converters to add more phases.

An output capacitor 124 is connected to each output voltage node. In the example of FIG. 1, an output capacitor 124-1 has a first end that is connected to the output voltage node 122 and a second end that is connected to power ground. Similarly, an output capacitor 124-2 has a first end that is connected to the output voltage node 123 and a second end that is connected to power ground. Other capacitors (e.g., supply capacitors) and other components not necessary to the understanding of the invention are not shown in FIG. 1 for clarity of illustration.

In one embodiment, a switch block 110 is implemented using an MP 86976 Intelli-Phase™ Solution monolithic IC, which is commercially-available from Monolithic Power Systems, Inc. Other suitable monolithic IC's may also be used without detracting from the merits of the present invention. A switch block 110 has, integrated therein, a driver 115 and a pair of switches M1, M2 (e.g., Metal-Oxide-Semiconductor Field-Effect Transistor (MOSFET)). Other circuits for implementing the driver 115, such as an auxiliary 3.3V power supply circuit, are not shown for clarity of illustration. As shown in FIG. 1, a switch block 110 has a first pin for receiving a pulse width modulation (PWM) signal, a second pin for receiving an input voltage VIN, a third pin for connecting to power ground, and a fourth pin that is connected to a switch node SW formed by the switches M1, M2. The drain of the switch M1 is connected to the input voltage VIN and the source of the switch M2 is connected to power ground. The source of the switch M1 is connected to the drain of the switch M2 at the switch node SW.

Generally speaking, PWM control is well-known in the art. Briefly, an external PWM controller 140 generates a PWM signal, which is received by a driver 115 at the first pin of the switch block 110. The driver 115 turns the switches M1, M2 ON and OFF in accordance with the PWM signal. Turning the switch M1 ON while turning the switch M2 OFF connects the input voltage VIN to the switch node SW (by way of the switch M1), whereas turning the switch M1 OFF while turning the switch M2 ON connects the switch node SW to power ground (by way of the switch M2). A first end of an output inductor 120 is connected to the switch node SW and a second end of the output inductor 120 is connected to an output voltage node (i.e., 122, 123) where an output voltage VOUT is developed. In the example of FIG. 1, the PWM controller 140 generates the PWM signals PWM1, PWM2 such that a corresponding output voltage VOUT is maintained in regulation. Other circuits for implementing the PWM control, such as sense circuits, are not shown for clarity of illustration.

The input voltage VIN, output voltage VOUT, and switching frequency of the switches M1, M2 depend on the particulars of the monolithic IC switch block 110. In one embodiment where the monolithic IC switch block 110 is implemented using the aforementioned MP 86976 Intelli-Phase™ Solution monolithic IC, the input voltage VIN is in the range of 3V to 7V, the output voltage VOUT is in the range of 0.4V to 2V (e.g., 0.8V), and the switching frequency of the switches M1, M2 is in the range of 1 MHz to 2 MHz (e.g., 1.5 MHz). The relatively low input voltage VIN and relatively high switching frequency of the switches M1, M2 allow for a relatively small physical size of the output inductor 120 (e.g., 2.5 mm×5 mm×1.2 mm). As will be more apparent below, the output inductor 120 may be embedded within the substrate of the power module 100 to achieve a low profile.

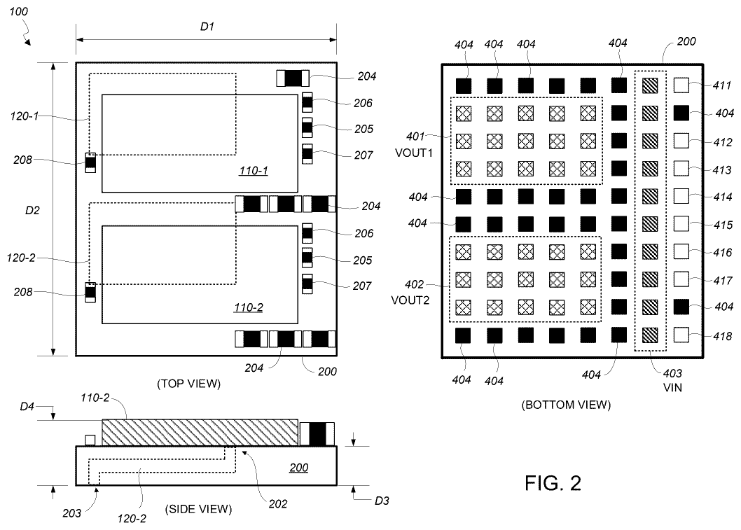

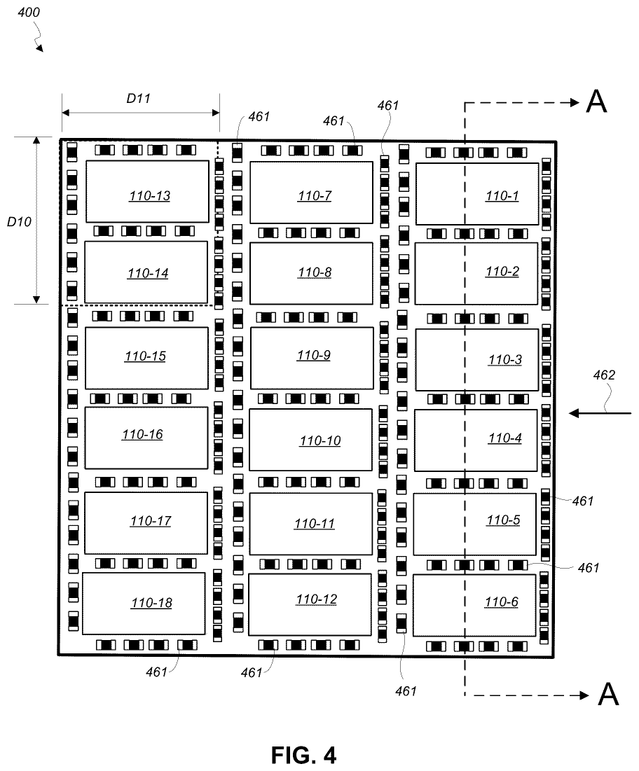

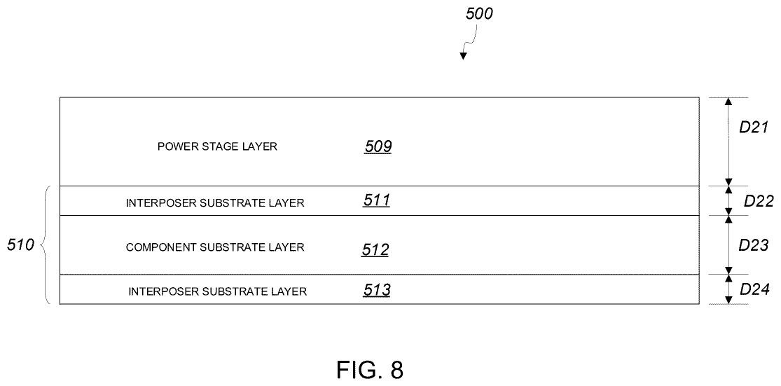

FIG. 2 shows, from the upper left hand corner in clock-wise direction, a top view, a bottom view, and a side view of a physical layout of the power module 100 in accordance with an embodiment of the present invention. The power module 100 has a substrate 200, which in one embodiment is a printed circuit board (PCB). The top view of the substrate 200 shows the “component side” of the substrate 200, whereas the bottom view shows the bottom side of the substrate 200. In the example of FIG. 2, the switch blocks 110, capacitors, and other components are mounted on the component side. In other embodiments, as will be later explained beginning with FIG. 4, output capacitors are disposed within a separate output capacitor substrate layer. In yet other embodiments, as will be later explained beginning with FIG. 8, output capacitors and output inductors are disposed within the same substrate layer.

In the example of FIG. 2, the bottom side, which is opposite the component side, has a plurality of pins that connect nodes of the power module 100 to components that are external to the power module 100, such as a PWM controller, etc. A pin may be a pad or other means for electrically connecting nodes and components. A pin may have a square (e.g., as in a land grid array), round (e.g., as in a ball grid array), or other shape. The power module 100 may be employed as part of a power supply (not shown). The pins of the power module 100 may be connected to corresponding sockets on a substrate of the power supply.

The top view of the power module 100 shows the switch block 110-1, switch block 110-2, and various capacitors mounted on the component side, such as input capacitors (e.g., see 204), capacitors of RC filters of supply voltages for internal digital logic control (e.g., 205, 207), bootstrap capacitors (e.g., see 206), filter capacitors of supply voltages for switch drivers (e.g., see 208), etc. As can be appreciated, the number and type of capacitors on the power module 100 depend on the particulars of the application. Generally, the capacitors on the power module 100 have relatively low capacitance. In the example of FIG. 2, a switch block 110 is the tallest component on the substrate 200. In one embodiment, the substrate 200 has a width D1 of about 8 mm; a length D2 of about 9 mm, and a substrate thickness D3 of about 1.5 mm. In one embodiment, a height D4 from the bottom surface of the substrate 200 to the topmost surface of a switch block 110 is 2.3 mm.

The output inductors 120-1 and 120-2, which are represented by dotted lines in FIG. 2, are embedded within the substrate 200. A first end of an output inductor 120 (see 202) is connected to a switch node of a corresponding switch block 110, and a second end of the output inductor 120 (see 203) is connected to a corresponding output voltage node. The relatively low inductance of each of the output inductors 120-1 and 120-2 in conjunction with the layout of the power module 100 allow the output inductors 120-1 and 120-2 to be embedded within the substrate 200, thereby lowering the profile of the power module 100. In one embodiment, the height D4 of the power module 100 is 2.3 mm and at most 5 mm.

In the example of FIG. 2, each pin of the power module 100 has a square shape, e.g., 0.45 mm×0.45 mm square. The pins that are connected to power ground, some of which are labeled as “404”, are depicted in black. Not all of the ground pins are labeled for clarity of illustration. The pins that are connected to the output voltage node 122 (shown in FIG. 1), where the output voltage VOUT1 is developed, are collectively labeled as “401”; the pins that are connected to the output voltage node 123 (shown in FIG. 1), where the output voltage VOUT2 is developed, are collectively labeled as “402”; and the pins that are connected to receive the input voltage VIN are collectively labeled as “403”. Pin 411 is connected to receive a PWM signal to the switch block 110-1; pin 418 is connected to receive a PWM signal to the switch block 110-2; pin 412 is connected to provide a current monitor signal from the switch block 110-1; pin 417 is connected to provide a current monitor signal from the switch block 110-2; pin 413 is connected to provide a temperature monitoring signal from the switch block 110-1; pin 416 is connected to provide a temperature monitoring signal from the switch block 110-2; pin 414 is connected to receive a VCC supply voltage; and pin 415 is connected to receive an enable signal. As can be appreciated, the pinout of the power module 100 depends on implementation details, such as the particular switch block 110 employed. The arrangement of the pins on the bottom surface of the substrate 200 may vary to suit particular applications.

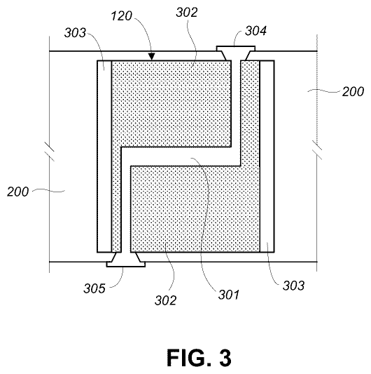

FIG. 3 shows a cross-sectional view of the substrate 200 in accordance with an embodiment of the present invention. FIG. 3 provides a schematic illustration of an output inductor 120 and is not to scale. In one embodiment, the output inductor 120 is a one turn inductor. The output inductor 120 may also have a few number of turns. The output inductor 120 comprises a conductor 301 and a magnetic core 302 that surrounds the conductor 301. In one embodiment, the conductor 301 comprises copper and the magnetic core 302 comprises a suitable core material, such as ferrite or powder iron. A gap 303 is between the magnetic core 302 and the substrate material, which in one embodiment comprises a PCB substrate. Generally speaking, a PCB is a laminated sandwich structure of conductive layers (e.g., copper) and insulating/dielectric layers (e.g., fiberglass epoxy laminate). The gap 303 may be an air gap that is filled with epoxy molding compound. A first end of the conductor 301 (see 304) comes out of the component side of the substrate 200 to connect to the switch node of a corresponding switch block 110, and a second end of the conductor 301 (see 305) comes out of the bottom side of the substrate 200 to a pin that is connected to a corresponding output voltage node.

In one embodiment, the output inductor 120 has an inductance less than 100 nH. As can be appreciated, the inductance of the output inductor 120 may vary depending on the volume of the substrate 200. Larger substrates allow physically larger inductors to be embedded. For example, with a thickness D3 (shown in FIG. 2) of 1.5 mm, the output inductor 120 may have dimensions of 2.5 mm×5 mm×1.2 mm with an inductance of about 30 nH.

FIG. 4 shows a top view of a physical layout of the power module 400 in accordance with an embodiment of the present invention. The top view of FIG. 4 shows a topmost surface of the PCB of the power module 400 where switch blocks 110 (i.e., 110-1, 110-2, . . . , 110-18), capacitors 461 (e.g., input capacitors, bootstrap capacitors, filter capacitors, supply capacitors, etc.), and other components (not shown) of the power module 400 are mounted. Each of the switch blocks 110 of the power module 400 may be employed in a power converter 130 as described in connection with FIG. 1. Generally speaking, the number of power converters on a power module, and thus the number of switch blocks, depends on the particulars of the application.

In the example of FIG. 4, the switch blocks 110 are physically arranged in groups of two (e.g., switch blocks 110-1 and 110-2 as one group; switch blocks 110-13 and 110-14 as another group; etc.), with each group of switch blocks having a length D10 of 8 mm and a width D11 of 8 mm. The switch blocks 110 may be configured to generate one or more output voltages. For example, the output voltage node of the switch block 110-1 may provide a first output voltage, and the output voltage node of the switch block 110-2 may provide a second output voltage, with each of the first and second output voltages being independent, separate output voltages. As another example, the output voltage nodes of the switch blocks 110-1 to 110-12 may be tied together to provide a first multiphase output voltage, and the output voltage nodes of the switch blocks 110-13 to 110-18 may be tied together to provide a second multiphase output voltage. All of the output voltages of the switch blocks 110 may also be tied together to generate a single multi-phase output voltage.

The power module 400 has 18 switch blocks 110 for illustration purposes only. As can be appreciated, more or less switch blocks 110 may be employed depending on the number of power converters provided by the power module 400. The specific layout of the components of the power module 400 may be configured to suit application details.

The power module 400 may be employed in various applications including graphics processing unit (GPU), central processing unit (CPU), application-specific integrated circuit (ASIC), etc. applications. During fast load transients, a sufficient number of output capacitors is required to limit output voltage undershoot and overshoot. However, output capacitors consume a lot of board space and decrease circuit density. This problem is especially troublesome in applications with a fixed board form factor, where the board space required by the output capacitors reduces the number of power converters available on the power module, thereby limiting the power that can be delivered to GPUs, CPUs, etc. In embodiments of the present invention, to conserve board space, an output capacitor of a power converter 130 is implemented by a plurality of parallel-connected discrete capacitors embedded within an output capacitor substrate layer of the PCB instead of on a topmost surface of the PCB.

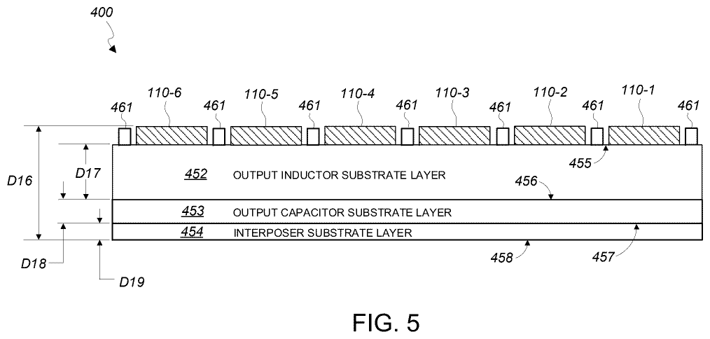

FIG. 5 shows a side view of the power module 400, as viewed in the direction of arrow 462 of FIG. 4. The power module 400 is implemented using a PCB comprising a plurality of substrate layers, namely an output inductor substrate layer 452, an output capacitor substrate layer 453, and an interposer substrate layer 454. Advantageously, the output inductor substrate layer 452 is between the switch blocks 110 and the output capacitor substrate layer 453 to allow a terminal of an output inductor to be efficiently connected to a switch node of a switch block 110.

In the example of FIG. 5, a top surface 455 of the output inductor substrate layer 452 serves as a topmost surface of the PCB on which the switch blocks 110, capacitors 461, and other components of the power module 400 are mounted. A bottom surface 458 of the interposer substrate layer 454 serves as the bottommost surface of the PCB on which pins of the power module 400 are exposed for external connection (e.g., as in the bottom view of FIG. 2). For example, the output voltage nodes 122 and 123 (shown in FIG. 1) may be connected to corresponding pins on the bottom surface 458 of the interposer substrate layer 454. A pin may have a square (e.g., as in a land grid array), round (e.g., as in a ball grid array), or other shape. As can be appreciated, the pinout of the power module 400 depends on implementation details, such as the particular switch blocks 110 employed. The arrangement of the pins on the bottom surface 458 may vary to suit particular applications.

In the example of FIG. 5, the output inductor substrate layer 452 has a bottom surface 456 that directly contacts a top surface of the output capacitor substrate layer 453. The interposer substrate layer 454 has a top surface 457 that directly contacts a bottom surface of the output capacitor substrate layer 453. In one embodiment, the output inductor substrate layer 452 has a thickness D17 of 2.32 mm, the output capacitor substrate layer 453 has a thickness D18 of 0.5 mm, and the interposer substrate layer 454 has a thickness D19 of 0.4 mm. The power module 400 has an overall height D16 of 4 mm measured from the bottom surface 458 of the interposer substrate layer 454 to a topmost surface of a tallest component mounted on the power module 400, which in one embodiment is a switch block 110. The power module 400 may have an overall height of at most 8 mm.

The output inductor substrate layer 452 provides a layer where the output inductors 120 (shown in FIG. 1) may be embedded within. The output inductors 120 may be embedded within the output inductor substrate layer 452 as explained with reference to FIGS. 2 and 3 except that an end of an output inductor 120 that extends out of the bottom surface now extends to the top surface of the output capacitor substrate layer 453. Electrical connections between and through the substrate layers 452-454 may be made by way of vias and/or nodes in the substrate layers 452-454.

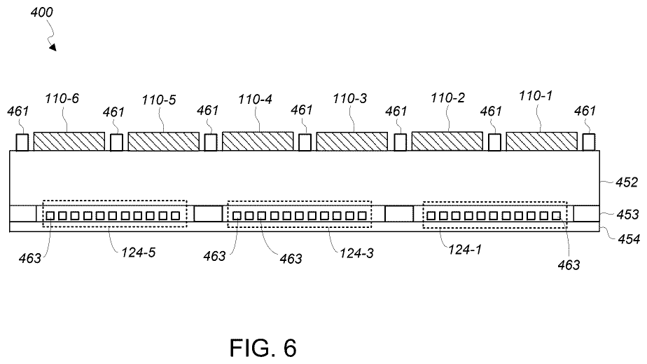

FIG. 6 shows a cross-sectional view of the power module 400 in accordance with an embodiment of the present invention. FIG. 6 is taken at cross-section A-A of FIG. 4. In one embodiment, an output capacitor 124 is implemented by a plurality of discrete (i.e., single, individual component; not part of an integrated circuit), embedded capacitors 463 that are connected in parallel and embedded within the output capacitor substrate layer 453. Note that not all of the embedded capacitors 463 are labeled in FIG. 6 for clarity of illustration. In one embodiment, an embedded capacitor 463 is a size 0201 capacitor. Other discrete capacitor sizes, such as size 0402, may also be used depending on available space in the output capacitor substrate layer 453 and the particular capacitance value of the output capacitor 124. The embedded capacitors 463 may be placed in one or more cavities or other carved out regions within the output capacitor substrate layer 453. In one embodiment, the embedded capacitors 463 are the only discrete components embedded within the output capacitor substrate layer 453. FIG. 6 shows the embedded capacitors 463 of the output capacitors 124-1, 124-3, and 124-5 in cavities embedded within the output capacitor substrate layer 453.

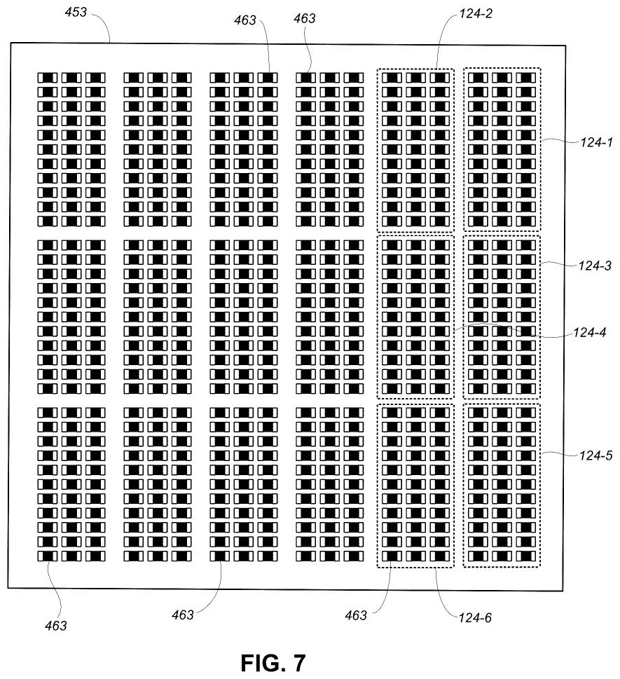

FIG. 7 shows the top view of the output capacitor substrate layer 453 in accordance with an embodiment of the present invention. In the example of FIG. 7, the embedded capacitors 463 are physically arranged in blocks of 33 discrete capacitors, with each block forming an output capacitor 124. The blocks of embedded capacitors 463 are arranged as a 6×3 array. FIG. 7 shows the embedded capacitors 463 that form the output capacitors 124-1, 124-2, 124-3, etc. Only some of the embedded capacitors 463 forming the output capacitors 124 are labeled for clarity of illustration.

In light of the present disclosure, one of ordinary skill in the art will appreciate that capacitors and inductors of power modules may also be embedded within the same substrate layer. For example, one or more output capacitors and inductors of power converters of a power module may be embedded within the same substrate layer of a multilayer PCB.

FIG. 8 shows a side view of a power module 500 in accordance with an embodiment of the present invention. The power module 500 comprises a power stage layer 509 and a substrate 510. In one embodiment, the substrate 510 is a multilayer PCB comprising an interposer substrate layer 511, a component substrate layer 512, and an interposer substrate layer 513. FIG. 8 is not drawn to scale. In one embodiment, the power stage layer has a thickness D21 of 0.8 mm, the substrate layer 511 has a thickness D22 of 0.33 mm, the substrate layer 512 has a thickness D23 of 1.5 mm, and the substrate layer 513 has a thickness D24 of 0.33 mm. The substrate 510 may have fewer or additional layers with different thicknesses depending on the application. The power stage layer 509 is disposed on the topmost layer of the substrate 510, which in the example of FIG. 8 is the interposer substrate layer 511.

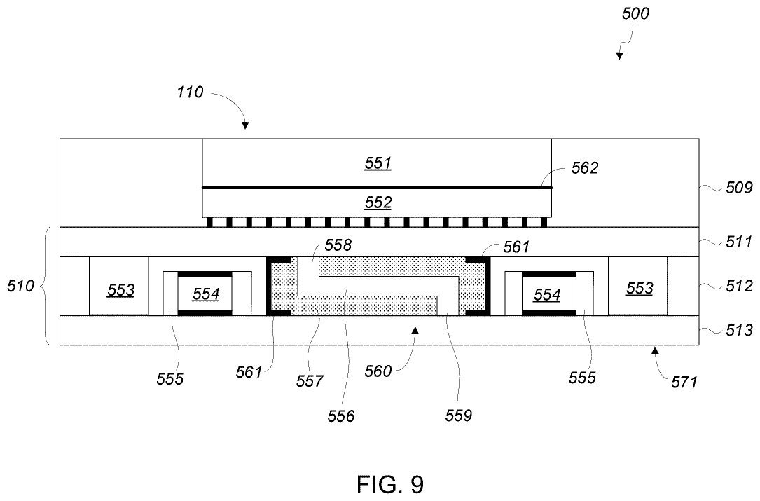

FIG. 9 shows a side cross-sectional view of the power module 500 in accordance with an embodiment of the present invention. In one embodiment, a switch block 110 is embedded within the power stage layer 509. In the example of FIG. 9, the switch block 110 is a DrMOS (Driver-MOSFET) comprising an integrated circuit (IC) die 552 and a copper block 551. The copper block 551 is disposed on a top surface of the IC die 552. The copper block 551 may be attached to the IC die 552 by a thermal interface material (TIM) 562, such as a thermal adhesive. The IC die 552 and copper block 551 may be encapsulated by molding compound, or other IC packaging material, within the power stage layer 509. In the example of FIG. 9, the copper block 551 is exposed to the environment on the topmost surface of the power stage layer 509. The heatsink 551 and the thermal interface material 562 are not needed in some applications, in which case the IC die 552 is mainly surrounded by molding compound.

In one embodiment, the IC die 552 embodies at least one driver 115 and a pair of switches M1, M2 (shown in FIG. 1). The power module 500 may have additional phases or output voltages by incorporating additional dies 552 in the power stage layer 509 or incorporating additional driver/switch pairs in each die 552. Disposing the power stage layer 509, and consequently the copper block 551, on the topmost layer of the substrate 510 advantageously improves heat dissipation.

In one embodiment, the substrate layer 511 is an interposer layer that includes vias and other interconnect structures for electrically connecting nodes of circuits incorporated in the die 552 to electronic components embedded within the substrate layer 512. Similarly, the substrate layer 513 is an interposer layer that includes vias and other interconnect structures for electrically connecting electronic components embedded within the substrate layer 512 to pins or pads on the bottom surface 571 of the substrate layer 513 or to other nodes/electronic components below the substrate layer 513. For example, pins on the bottom surface 571 of the substrate layer 513 may interface to other components that are external to the power module 500, such as a PWM controller, etc. Such other components may be on another substrate or substrate layer that is below the substrate layer 513.

Embedded within the substrate layer 512 are electronic components, which in one embodiment are one or more capacitors 554 and one or more inductors 560. In one embodiment, the substrate layer 512 has cavities 555 (or other carved out region) where the capacitors 554 are disposed. A capacitor 554 may be a size 0201 discrete capacitor, for example.

In the example of FIG. 9, the inductor 560 is a single turn inductor that comprises a conductor 556 and a magnetic core 557. In one embodiment, the inductor 560 and the capacitors 554 function as an output inductor 120 and output capacitor 124, respectively, of a power converter 130 (shown in FIG. 1) of the power module 500. A first end of the capacitor 554 is electrically connected to an end 559 of the conductor 556, and a second end of the capacitor 554 is electrically connected to power ground. The end 559 of the conductor 556 is electrically connected to an output voltage node of the power module 500, and an end 558 of the conductor 556 is electrically connected to a switch node SW of a corresponding pair of switches M1, M2 integrated in the die 552. As can be appreciated, electrical connections may be made by way of vias and other interconnect structures in the substrate layers 511 and 513, as appropriate.

In the example of FIG. 9, copper blocks 553 and interconnect structures 561 function as vias to provide an electrical connection through the substrate layer 512. In one embodiment, the interconnect structures 561 are attached to the sidewalls of the magnetic core 557. Other interconnect structures may also be used without detracting from the merits of the present invention.

FIG. 9 depicts a single switch block 110 for clarity of illustration. As can be appreciated, the power module 500 may include a plurality of switch blocks 110. For example, a plurality of IC dies 552 may be embedded within the power stage layer 509, with each IC die 552 having a driver 115 and a pair of switches M1, M2 of a power converter 130. A plurality of inductors 560 and capacitors 554 may be embedded within the substrate layer 512 to provide output inductors and output capacitors to the plurality of power converters 130.

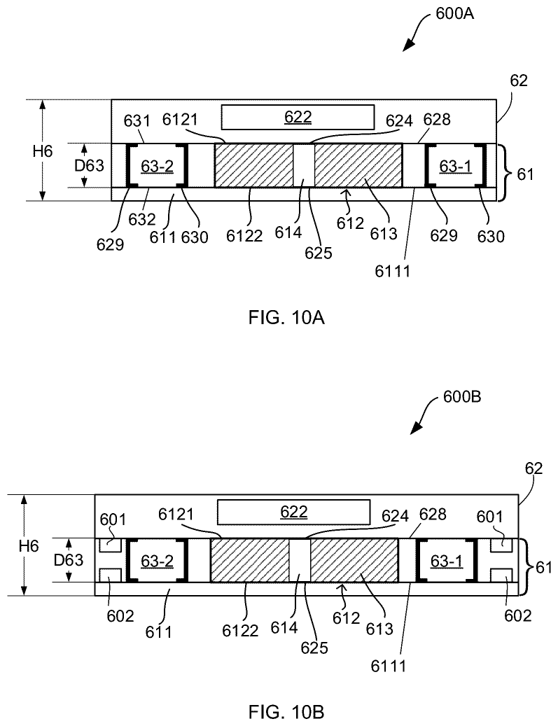

FIG. 10A shows a side cross-sectional view of a power module 600A in accordance with an embodiment of the present invention. The power module 600A comprises a passive component layer 61 and an active layer 62 disposed on the passive component layer 61. FIG. 10A is not drawn to scale. As will be more apparent below, the input capacitor 125 and the output inductor 120 may be placed in the passive component layer 61 of the power module 600A to achieve a low profile. In one embodiment, the output capacitor 124 may further be placed in the passive component layer 61. In one embodiment, the switch block 110 is formed within the active layer 62. For example, an IC die 622 embodying at least one driver 115 and a pair of switches M1, M2 (shown in FIG. 1) may be embedded in or be disposed on a substrate in the active layer 62. The power module 600A may have additional phases or output voltages by incorporating additional IC dies in the active layer 62 or incorporating additional driver/switch pairs in each IC die.

In the example of FIG. 10A, the passive component layer 61 has a substrate 611, and a plurality of passive components, such as at least one magnetic device 612, and capacitors 63 (i.e., 63-1, 63-2). More magnetic devices 612 may be included in the passive component layer 61 according to different applications. In one example, the magnetic device 612 comprises the output inductor 120. The magnetic device 612 has a magnetic core 613 and at least one turn 614 embedded in the magnetic core 613. The turn 614 and the magnetic core 613 that surrounds the turn 614 forms the output inductor 120. The turn 614 has a first end 624 extended to a top surface 6121 of the magnetic device 612 and is electrically connected to a switch node SW of a corresponding pair of switches M1, M2. The turn 614 further has a second end 625 extended to a bottom surface 6122 of the magnetic device 612 and is electrically connected the output voltage node of the power module 600A. In one embodiment, a top surface of the magnetic core 613 is the top surface 6121 of the magnetic device 612, and a bottom surface of the magnetic core 613 is the bottom surface 6122 of the magnetic device 612. The magnetic device 612 may have more turns 614 to form more output inductors 120 for additional phases or output voltages.

In the example of FIG. 10A, the magnetic device 612 and the capacitors 63 are attached between a top surface 6111 of the substrate 611 and a bottom surface 628 of the active layer 62 (e.g., a bottom surface of a substrate in the active layer 62), the top surface 6111 of the substrate 611 faces toward the bottom surface 628 of the active layer 62. As shown in FIG. 10A, the top surface 6121 of the magnetic device 612 touches the bottom surface 628 of the active layer 62, the bottom surface 6122 of the magnetic device 612 touches the top surface 6111 of the substrate 611, a top surface 631 of the capacitors 63 touches the bottom surface 628 of the active layer 62, and a bottom surface 632 of the capacitors 63 which is opposite the top surface 631 touches the top surface 6111 of the substrate 611.

Each of the capacitor 63 has two conducting terminals 629-630 extended as vias between the bottom surface 628 of the active layer 62 and the top surface 6111 of the substrate 611 to provide electrical connections between the substrate 611 and the active layer 62 respectively. The capacitors 63 (e.g., 63-1 shown in FIG. 10) may comprise the input capacitor 125 shown in FIG. 1. One of the conducting terminals 629-630 of the input capacitor 63-1 is configured to transmit the input voltage VIN received from input pins of the power module 600A, and the other one of the conducting terminals 629-630 of the input capacitor 63-1 is connected to the power ground. The capacitors 63 (e.g., 63-2 shown in FIG. 10) may further comprise the output capacitor 124 shown in FIG. 1. One of the conducting terminals 629-630 of the output capacitor 63-2 is electrically connected to the second end 625 of the turn 614 to provide the output voltage VOUT to output pins of the power module 600A, and the other one of the conducting terminals 629-630 is connected to the power ground.

In an exemplary embodiment, electrical connections between the active layer 62 and the substrate 611 is made by way of vias formed by conducting terminals 629-630 of the capacitors 63, the turn 614, and interconnect structures of the magnetic device 612 (not shown in FIG. 10). No dedicated connector, such as a copper pillar, is needed between the active layer 62 and the substrate 611, which saves area, while the size of the power module 600A is further reduced. In one embodiment, the capacitors 63 and the magnetic device 612 have a same height D63 of about 0.85 mm, at most 1.5 mm. The power module 600A has a whole height H6 of about 1.8 mm, at most 2 mm.

FIG. 10B shows a side cross-sectional view of a power module 600B in accordance with an embodiment of the present invention. The power module 600B further has a set of capacitors 601 and a set of capacitors 602 face towards the set of capacitors 601 respectively. The set of capacitors 601 are attached to the bottom surface 628 of the active layer 62, and the set of capacitors 602 are attached to the top surface 6111 of the substrate 611. Each of the capacitors 601, 602 has a height that is lower than the height D63 of the capacitor 63 and the magnetic device 612.

FIG. 10C shows a three-dimensional (3D) view of the capacitor 63 in accordance with an embodiment of the present invention. The conducting terminal 629 of the capacitor 63 has a first end 629-1 soldered to the bottom surface 628 of the active layer 62, and a second end 629-2 soldered to the top surface 6111 of the substrate 611. The conducting terminal 630 of the capacitor 63 has a first end 630-1 soldered to the bottom surface 628 of the active layer 62, and a second end 630-2 soldered to the top surface 6111 of the substrate 611.

FIG. 10D shows a 3D transparent view of the capacitor 63 in accordance with another embodiment of the present invention. In the example of FIG. 10D, the capacitor 63 has a plurality of vertically stacked copper layers 633 which are perpendicular to the top and bottom sides of the capacitor 63. A first group 633-1 of the vertically stacked copper layers 633 are electrically connected to the conducting terminal 629, and a second group 633-2 of the vertically stacked copper layers 633 are electrically connected to the conducting terminal 630. Insulating material, e.g., ceramic, is filled between each of the horizontally stacked copper layers 633. With the vertically stacked copper layers 633, an impedance between top and bottom of the capacitor 63 is reduced. And the vertically stacked copper layers 633 further provide current conduct paths between top and bottom of the capacitor 63. In one example, the first group 633-1 and the second group 633-2 of the vertically stacked copper layers 633 are arranged in an inter-digital pattern.

FIG. 10E shows a 3D transparent view of the capacitor 63 in accordance with yet another embodiment of the present invention. In the example of FIG. 10E, the capacitor 63 has a plurality of horizontally stacked copper layers 634 which are in parallel with the top and bottom sides of the capacitor 63. A first group 634-1 of the horizontally stacked copper layers 634 are electrically connected to the conducting terminal 629, and a second group 634-2 of the horizontally stacked copper layers 634 are electrically connected to the terminal 630.

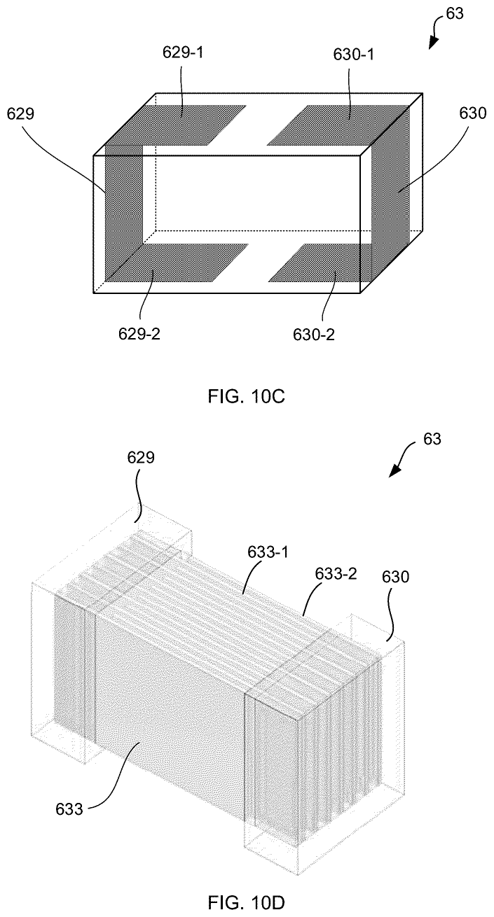

FIG. 11 shows a 3D transparent view of a power module 700 in accordance with an embodiment of the present invention. The power module 700 is a particular embodiment of the power module 600A or 600B. In the example of FIG. 11, the active layer 62 has a substrate 621, IC dies 622 and capacitors 623 (e.g., input capacitors) disposed on a top surface of the substrate 621. The IC dies 622 and the capacitors 623 may be encapsulated by molding compound, or other IC packaging material. In the example of FIG. 11, the power module 700 has four IC dies 622 for illustration purposes. As described above, the power module 700 may have more or less IC dies 622 to provide appropriate phases or output voltages, and each IC die 622 may have one or more drivers and pairs of switches without detracting from embodiments of the present invention. The specific layout of the components of the power module 700 may be configured to suit application details.

In the example of FIG. 11, a bottom surface of the substrate 621 which is opposite the top surface of the substrate 621 is the bottom surface 628 (as shown in FIGS. 10A-10B) of the active layer 62. One or more magnetic devices 612 and capacitors 63 are attached between the bottom surface of the substrate 621 and the top surface 6111 (as shown in FIGS. 10A-10B) of the substrate 611. In one embodiment, the capacitors 63 comprise the input capacitor 125 as shown in FIG. 1 has two conducting terminals configured as vias to provide electrical connections between the substrate 611 and the substrate 621 respectively. In one embodiment, the capacitors 63 further comprise the output capacitor 126 as shown in FIG. 1. In one embodiment, conducting terminals of the capacitors 63 electrically connect nodes (e.g., the input voltage node and the power ground node) of the substrate 611 to nodes of the substrate 621.

In one embodiment, the power module 700 has a relatively small physical size, e.g., about 9.5 mm×10 mm×1.8 mm for 8 phases or for 8 output voltages as one example, at most 10 mm×11 mm×2 mm. In one embodiment, the height H6 of the power module 700 is about 1.8 mm, and at most 2 mm.

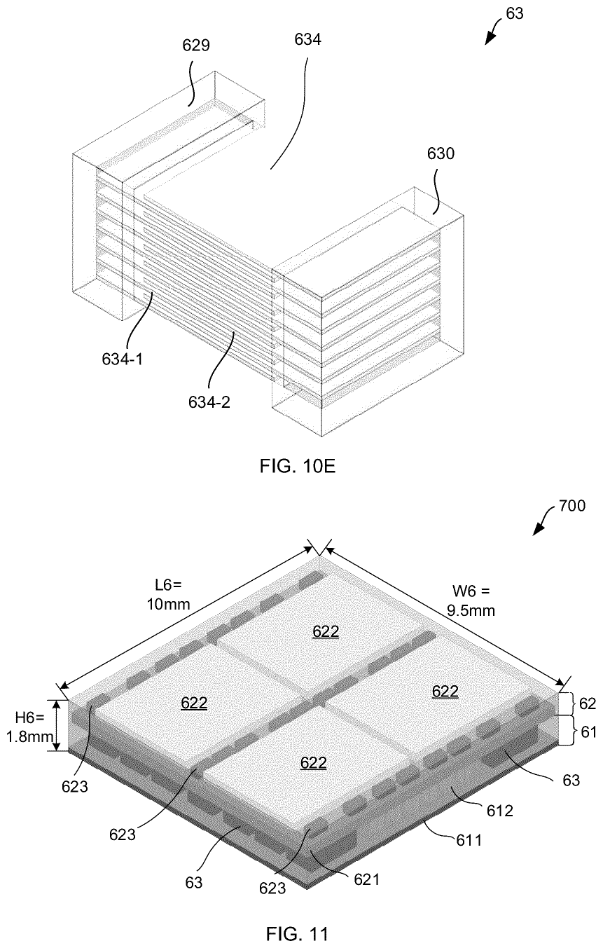

FIG. 12 shows a top view of a physical layout of the substrate 621 of the power module 700 in accordance with an embodiment of the present invention. In the example of FIG. 12, the IC dies 622 (i.e., 622-1, 622-2, 622-3, 622-4), the capacitors 623 (e.g., input capacitors CIN, bootstrap capacitors CB1-CB8 and supply capacitors CD1-CD8 for powering the driver), and other components (not shown) of the power module 700 are mounted on the substrate 621. Each IC die 622 may comprise two power blocks 110, that is two pairs of switches and associated drivers. Each IC die 622 may have more or less power block 110 to suit different applications. In the example of FIG. 12, the substrate 621 has a length L7 of about 9.85 mm, and a width W7 of about 9.35 mm.

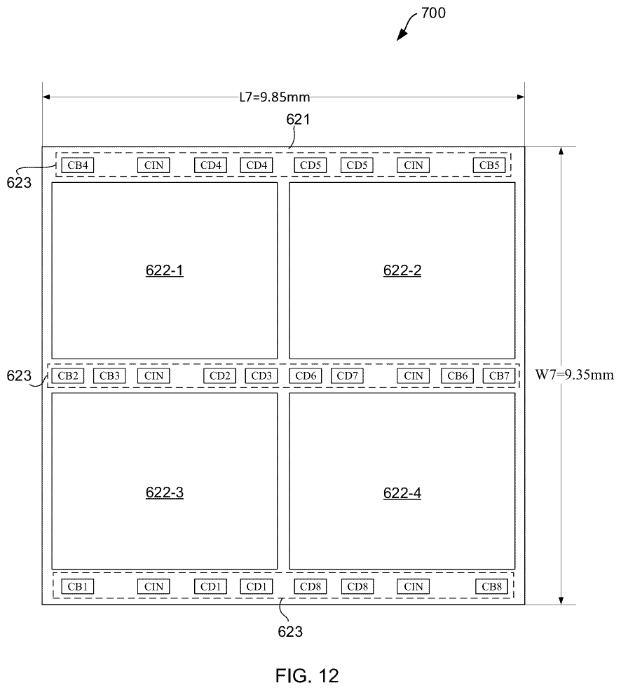

FIG. 13 shows a top view of a physical layout of the substrate 611 of the power module 700 in accordance with an embodiment of the present invention. In the example of FIG. 13, two magnetic devices 612 (i.e., 612-1, 612-2) and the capacitors 63 (i.e., 63-1, 63-2) are mounted on the substrate 611. The power module 700 has two magnetic devices 612 for illustration purposes. As can be appreciated, more or less magnetic devices 612 may be employed to suit application details. In one embodiment, each magnetic device 612 with four output inductors has a length L1 of about 4.5 mm, at most 5 mm, and a width W1 of about 3.6 mm, at most 4 mm.

In the example of FIG. 13, each magnetic device 612 comprises four turns 614 (i.e., 614-1, 614-2, 614-3, 614-4) which are embedded in the magnetic core 613 to form four output inductors 120. As can be appreciated, more or less output inductors 120 may be formed by the magnetic device 612 to suit application details. In the example of FIG. 13, each magnetic device 612 further comprises interconnect structures 615 which are collectively labeled and are placed along a side of the magnetic core 613. In one embodiment, each magnetic device 612 has one or more interconnect structures 615 embedded in or attached to the sidewalls of the magnetic core 613 as vias to provide electrical connections between the substrate 611 and the substrate 621, e.g., to conduct signals, such as a PWM signal for controlling the pairs of switches in IC dies 622, an enabling signal for enabling the pairs of switches, a temperature monitoring signal for monitoring temperature of the pairs of switches, a current monitoring signal for monitoring a current flowing through the pairs of switches, etc.

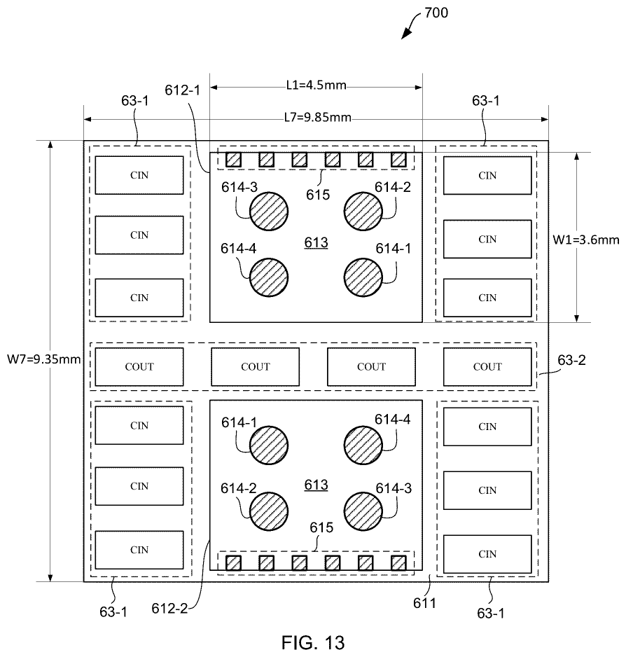

FIG. 14 shows a bottom view of the power module 700 in accordance with an embodiment of the present invention. As shown in FIG. 14, a bottom side of the power module 700 (e.g., a bottom surface of the substrate 611) has a plurality of pins that connect nodes of the power module 700 to components that are external to the power module 700, such as a PWM controller, etc. A pin may be a pad or other structure (e.g. bump, ball, pillar, etc.) for electrically connecting nodes and components. A pin may have a square, a rectangle, a round, or other shape.

In the example of FIG. 14, some of the pins have a square shape, e.g., 0.4 mm×0.4 mm square, some of the pins have a rectangle shape, e.g., 1.4 mm×2.8 mm rectangle and 0.4 mm×1.0 mm for the pins that are connected to the input voltage VIN, yet some of the pins have a rectangle shape, e.g., 1.3 mm×1.4 mm rectangle, 2.6 mm×2.8 mm rectangle, and 2.6 mm×1.3 mm rectangle for the pins that are connected to the output voltage VOUT, yet some of the pins have a rectangle shape, e.g., 2.8 mm×1.4 mm rectangle and 0.4 mm×1.0 mm rectangle for the pins that are connected to the power ground GND. The ground pins are connected to the power ground GND, some of which are labeled as “704”, depicted in black. Not all of the ground pins are labeled for clarity of illustration. The output pins are configured to provide the output voltage VOUT, some of which are labeled as “702”, depicted in diamond lines. Not all of the output pins are labeled for clarity of illustration. The input pins are configured to receive the input voltage VIN, some of which are labeled as “703”, depicted in downward diagonal lines. Not all of the input pins are labeled for clarity of illustration. Pin 705 is configured to receive a PWM signal PWM1 to control the switches in the IC die 622-1; pin 706 is configured to receive an enable signal EN1 (e.g., to enable the IC dies 622-1 and 622-2); pin 707 is configured to provide a current monitoring signal CS1 from the IC die 622-1; pin 708 is configured to provide a current monitoring signal CS2 from the IC die 622-2; pin 709 is configured to receive a supply voltage VCC; pin 710 is configured to receive a PWM signal PWM2 to control the switches in the IC die 622-2; pin 711 is configured to receive a PWM signal PWM3 to control the switches in the IC die 622-3; pin 712 is configured to provide a temperature monitoring signal TMON from all of the IC dies 622; pin 712 is configured to provide a current monitoring signal CS3 from the IC die 622-3; pin 713 is configured to provide a current monitoring signal CS4 from the IC die 622-4; pin 715 is configured to receive an enable signal EN2 (e.g., to enable the IC dies 622-3 and 622-4); and pin 716 is configured to receive a PWM signal PWM4 to control the switches in the IC die 622-4. As can be appreciated, the pinout of the power module 700 depends on implementation details, and the arrangement of the pins on the bottom side of the power module 700 may vary to suit particular applications.

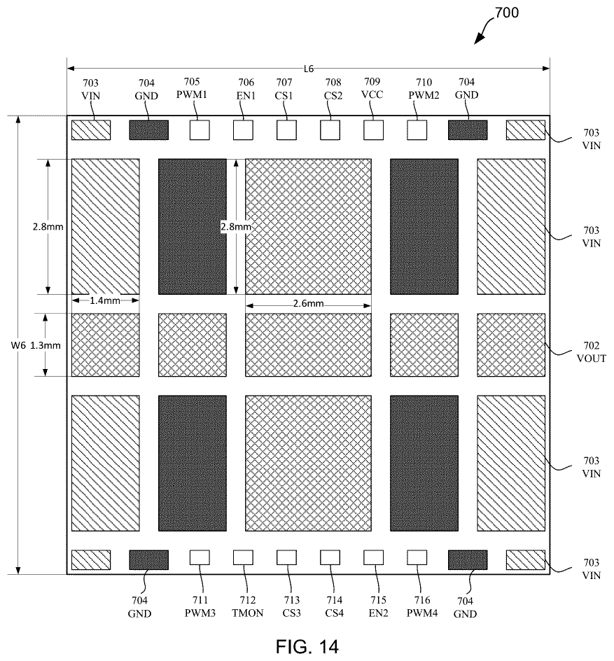

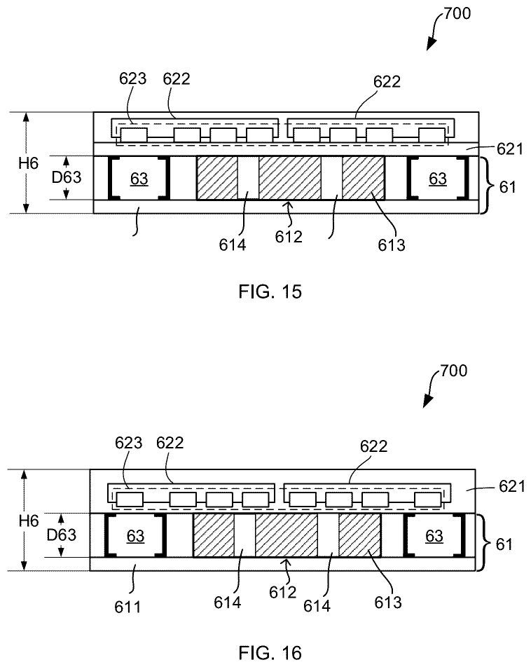

FIG. 15 shows a side cross-sectional view of the power module 700 of FIG. 13 in accordance with an embodiment of the present invention. In the example of FIG. 15, the IC dies 622 and the collectively labeled capacitors 623 are disposed on the substrate 621. FIG. 16 shows a side cross-sectional view of the power module 700 of FIG. 13 in accordance with another embodiment of the present invention. In the example of FIG. 16, the IC dies 622 and the capacitors 623 are embedded in the substrate 621.

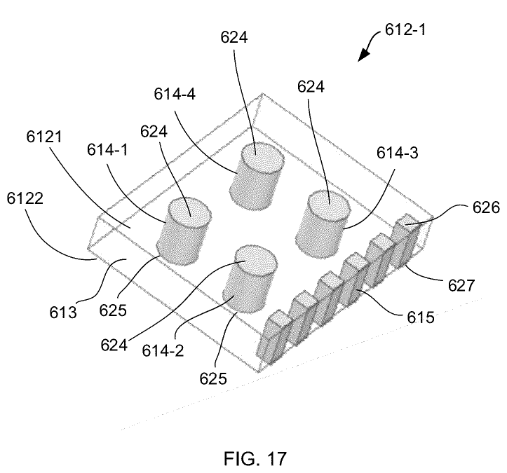

FIG. 17 shows a 3D transparent view of the magnetic device 612-1 in accordance with an embodiment of the present invention. FIG. 17 illustrates the magnetic device 612-1 as one example, the magnetic device 612-2 is similar to the magnetic device 612-1, and is not illustrated for clarity. The magnetic device 612-1 has four turns 614 (i.e., 614-1, 614-2, 614-3, 614-4) embedded in the magnetic core 613 to form four output inductors 120. Each turn 614 and the magnetic core 613 that surrounds the turn 614 forms one output inductor 120. The magnetic device 612-1 of FIG. 17 is illustrated as having four inductors as one example, more or less turns may be embedded in the magnetic core 613 to form more or less inductors in other examples. In one embodiment, each output inductor 120 of FIG. 17 has an inductance less than 30 nH. As can be appreciated, the inductance of each output inductor 120 may vary depending on a height of the magnetic device 612. For example, with the height D63 (shown in FIG. 10) of 0.85 mm, the magnetic device 612 may have dimensions of 3.6 mm×4.5 mm×0.85 mm with four output inductors each having an inductance of about 25 nH.

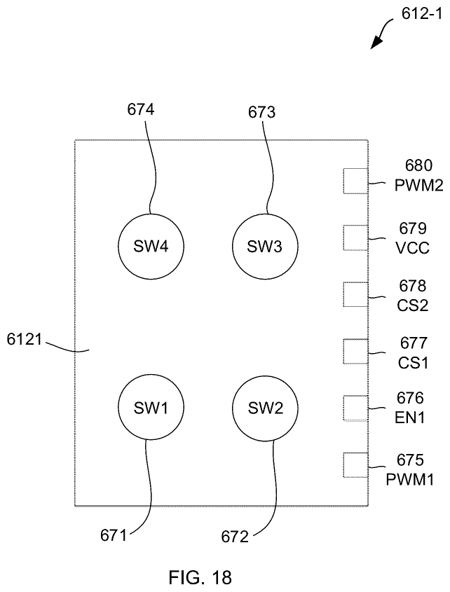

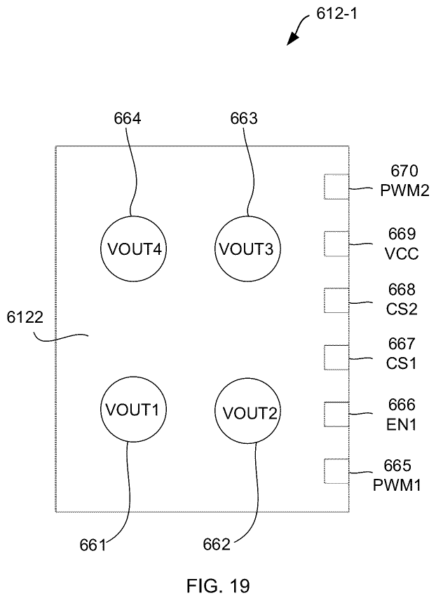

As shown in FIG. 17, each turn 614 has the first end 624 extended to the top surface 6121 of the magnetic device 612-1 and the second end 625 extended to the bottom surface 6122 of the magnetic device 612-1. The first end 624 is electrically connected to a contact pad on the top surface 6121 of the magnetic device 612-1. The second end 625 is electrically connected to a contact pad on the bottom surface 6122 of the magnetic device 612-1. For example, the first end 624 of the turn 614-1 is electrically connected to a contact pad 671 (as shown in FIG. 18) on the top surface 6121 of the magnetic device 612-1, the first end 624 of the turn 614-2 is electrically connected to a contact pad 672 (as shown in FIG. 18) on a top surface 6121 of the magnetic device 612-1, the first end 624 of the turn 614-3 is electrically connected to a contact pad 673 (as shown in FIG. 18) on the top surface 6121 of the magnetic device 612-1, the first end 624 of the turn 614-4 is electrically connected to a contact pad 674 (as shown in FIG. 18) on the top surface 6121 of the magnetic device 612-1. For example, the second end 625 of the turn 614-1 is electrically connected to a contact pad 661 (as shown in FIG. 19) on the bottom surface 6122 of the magnetic device 612-1, the second end 625 of the turn 614-2 is electrically connected to a contact pad 662 (as shown in FIG. 19) on the bottom surface 6122 of the magnetic device 612-1, the second end 625 of the turn 614-3 is electrically connected to a contact pad 663 (as shown in FIG. 19) on the bottom surface 6122 of the magnetic device 612-1, the second end 625 of the turn 614-4 is electrically connected to a contact pad 664 (as shown in FIG. 19) on the bottom surface 6122 of the magnetic device 612-1. In the example of FIG. 17, the turns 614 are illustrated as cylinder shapes, but other shapes may also be employed to suit different applications.

In the example of FIG. 17, the interconnect structures 615 is embedded in the magnetic core. Each interconnect structure 615 has a first end 626 and a second end 627, wherein the first end 626 is electrically connected to a contact pad (e.g., one of contact pads 675-680 as shown in FIG. 18) on the top surface 6121 of the magnetic device 612-1, the second end 627 is electrically connected to a contact pad (e.g., one of contact pads 665-670 as shown in FIG. 19) on the bottom surface 6122 of the magnetic device 612-1. Not all interconnect structures 615 are labeled in FIG. 17 for clarity of illustration. In the example of FIG. 17, the interconnect structures 615 are illustrated as rectangular shapes, but other shapes may also be employed to suit different applications.

FIG. 18 shows a top view of the top surface 6121 of the magnetic device 612-1 of FIG. 17 in accordance with an embodiment of the present invention. FIG. 18 shows contact pads of the magnetic device 612-1 that interface with the bottom surface of the substrate 621, to electrically connect to corresponding nodes on the IC dies 622 (e.g., 622-1 and 622-2) via the substrate 621.

In the example of FIG. 18, the contact pad 671 electrically connects to a first switch node (e.g., SW1 formed by a first pair of switches for a first phase), the contact pad 672 electrically connects to a second switch node (e.g., SW2 formed by a second pair of switches for a second phase), the contact pad 673 electrically connects to a third switch node (e.g., SW3 formed by a third pair of switches for a third phase), the contact pad 674 electrically connects to a fourth switch node (e.g., SW4 formed by a fourth pair of switches for a fourth phase). The contact pad 675 electrically connects to the gates of switches in one of the IC dies 622 (e.g., 622-1 for the first and second phases) to provide the PWM signal (e.g., PWM1), the contact pad 676 is configured to provide the enable signal EN1 (e.g., to enable the IC dies 622-1 and 622-2), the contact pad 677 is configured to receive the current monitoring signal CS1 (e.g., from the IC dies 622-1), the contact pad 678 is configured to receive the current monitoring signal CS2 (e.g., from the IC dies 622-2), the contact pad 679 electrically connects to receive the supply voltage VCC, and the contact pad 680 electrically connects to the gates of switches in another one of the IC dies 622 (e.g., 622-2 for the third and fourth phases) to provide the PWM signal (e.g., PWM2).

In one example, the top surface 6121 of the magnetic device 612-2 could also have contact pads similar to contact pads 671-674 electrically connects to switch node respectively (e.g., a fifth switch node formed by a fifth pair of switches for a fifth phase, a sixth switch node formed by a sixth pair of switches for a sixth phase, a seventh switch node formed by a seventh pair of switches for a seventh phase, and a eighth switch node formed by a eighth pair of switches for a eighth phase). In another example, the top surface 6121 of the magnetic device 612-2 could also have contact pads similar to contact pads 675-680 to conduct signals (e.g., PWM3, PWM4, TMON, CS3, CS4, EN2).

FIG. 19 shows a bottom view of the bottom surface 6122 of the magnetic device 612-1 of FIG. 17 in accordance with an embodiment of the present invention. FIG. 19 shows contact pads of the magnetic device 612-1 that interface with a top surface of the substrate 611, to electrically connect to corresponding pins of the power module 700 via the substrate 611.

In the example of FIG. 19, the contact pad 661 electrically connects to provide an output voltage VOUT1 of the first phase, the contact pad 662 electrically connects to provide an output voltage VOUT2 of the second phase, the contact pad 663 electrically connects to provide an output voltage VOUT3 of the third phase, the contact pad 664 electrically connects to provide an output voltage VOUT4 of the fourth phase. The contact pad 665 is configured to receive the PWM signal (e.g., PWM1), the contact pad 666 is configured to receive the enable signal EN1, the contact pad 667 is configured to provide the current monitoring signal CS1, the contact pad 668 is configured to provide the current monitoring signal CS2, the contact pad 669 is configured to receive the supply voltage VCC, and the contact pad 670 is configured to receive the PWM signal (e.g., PWM2).

In one example, the bottom surface 6122 of the magnetic device 612-2 could also have contact pads similar to contact pads 661-664 electrically connects to provide an output voltage VOUT respectively (e.g., VOUT5-VOUT8 for the fifth phase to the eighth phase). In another example, the bottom surface 6121 of the magnetic device 612-2 could also have contact pads similar to contact pads 665-670 to conduct signals, (e.g., PWM3, PWM4, TMON, CS3, CS4, EN2).

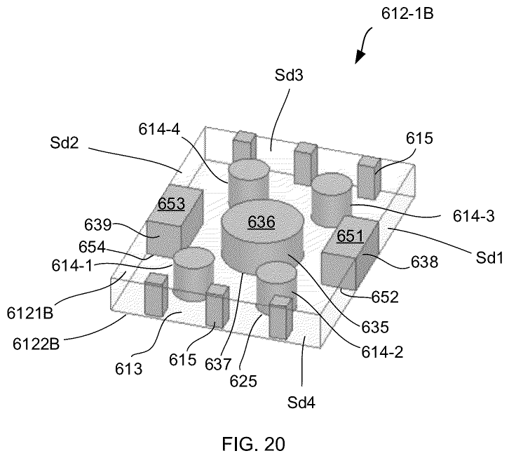

FIG. 20 shows a 3D transparent view of a magnetic device 612-1B in accordance with an embodiment of the present invention. The magnetic device 612-1B is another embodiment of the magnetic device 612-1. In the embodiment of FIG. 20, the magnetic device 612-1B further has a shared turn 635 extended between the top surface 6121B and the bottom surface 6122B of the magnetic device 612.

The magnetic device 612-1B has four turns 614 (i.e., 614-1, 614-2, 614-3, 614-4) and the shared turn 635 embedded in the magnetic core 613 to form four output inductors 120. In the example of FIG. 20, the shared turn 635 is shared by the output inductors (e.g., 120-1, 120-2, 120-3, 120-4) formed by the magnetic device 612, to increase inductance of each output inductor. The magnetic device 612-1B of FIG. 20 is illustrated as having four inductors as one example, more or less inductors may be formed in other examples. In one embodiment, the shared turn 635 is disposed in an area surrounded by the turns 614 (i.e., 614-1, 614-2, 614-3, 614-4 shown in FIG. 20). In one embodiment, each output inductor of FIG. 20 has an inductance less than 50 nH. For example, with the height D63 (shown in FIG. 10) of 0.85 mm, the magnetic device 612-1B may have dimensions of 3.6 mm×4.5 mm×0.85 mm with four output inductors each having an inductance of about 35 nH.

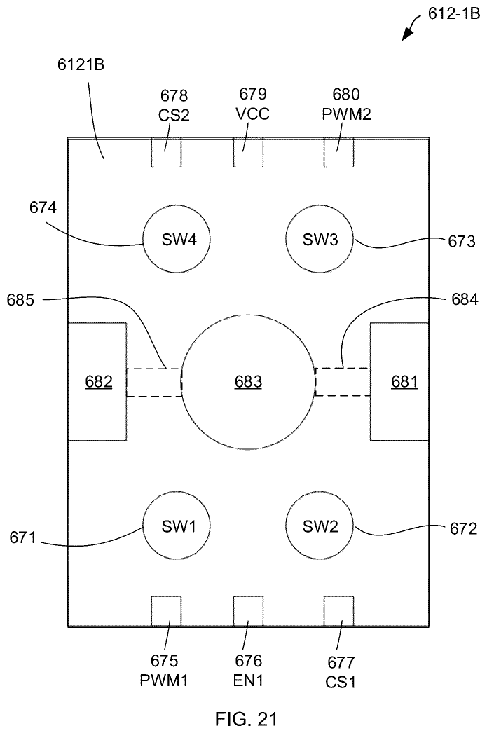

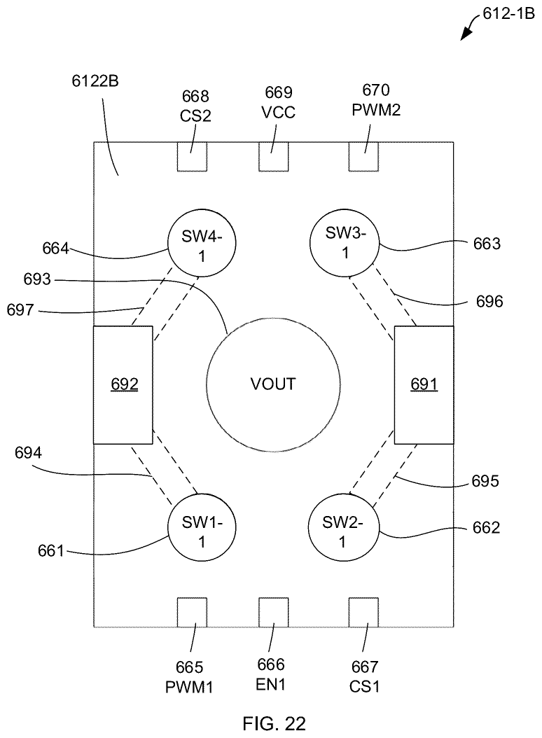

In the example of FIG. 20, the shared turn 635 has a first end 636 electrically connected to a contact pad 683 (as shown in FIG. 21) on a top surface 6121B of the magnetic device 612-1B, and a second end 637 electrically connected to a contact pad 693 (as shown in FIG. 22) on a bottom surface 6122B of the magnetic device 612-1B. A connector 638 and a connector 639 are embedded in or placed on surfaces of the magnetic core 613. The distance between the connector 638 and the turn 614-2 is the same as that between the connector 638 and the turn 614-3. The distance between the connector 639 and the turn 614-1 is the same as that between the connector 639 and the turn 614-4. In the example of FIG. 20, the connector 638 is placed along a side Sd1 of the magnetic device 612-1B, and the connector 639 is placed along a side Sd2 of the device 612B which is opposite the side Sd1 of the magnetic core 613. In the example of FIG. 20, some of the interconnect structures 615 are placed along a side Sd3 of the magnetic device 612, while some of the interconnect structures 615 are placed along a side Sd4 of the magnetic device 612 which is opposite the side Sd3.

In the example of FIG. 20, the connector 638 has a first end 651 extended to the top surface 6121B of the magnetic device 612-1B and a second end 652 extended to the bottom surface 6122B of the magnetic device 612-1B. The first end 651 of the connector 638 is electrically connected to a contact pad 681 (as shown in FIG. 21) on the top surface 6121B of the magnetic device 612-1B, to electrically connect to the first end 636 of the shared turn 635. The second end 652 of the connector 638 is electrically connected to a contact pad 691 (as shown in FIG. 22) on the bottom surface 6122B of the magnetic device 612-1B, to electrically connect to the second end 625 of the turn 614-2 and the second end 625 of the turn 614-3. In the example of FIG. 20, the connector 639 has a first end 653 extended to the top surface 6121B of the magnetic device 612-1B and a second end 654 extended to the bottom surface 6122B of the magnetic device 612-1B. The first end 653 of the connector 639 is electrically connected to a contact pad 682 (as shown in FIG. 21) on the top surface 6121B of the magnetic device 612-1B, to electrically connect to the first end 636 of the shared turn 635. The second end 654 of the connector 639 is electrically connected to a contact pad 692 (as shown in FIG. 22) on the bottom surface 6121B of the magnetic device 612-1B, to electrically connect to the second end 625 of the turn 614-1 and the second end 625 of the turn 614-4.

FIG. 21 shows a top view of the top surface 6121B of the magnetic device 612-1B of FIG. 20 in accordance with an embodiment of the present invention. FIG. 21 shows contact pads of the magnetic device 612-1B that interface with the bottom surface of the substrate 621, to electrically connect to corresponding nodes on the IC dies 622 via the substrate 621. Compared with the top surface 6121 of the magnetic device 612, the top surface 6121B of the magnetic device 612-1B further has contact pads 681-683. A trace 684 electrically connects the contact pad 683 to the contact pad 681, and a trace 685 electrically connects the contact pad 682 to the contact pad 681. The traces 684 and 685 may be formed in the substrate 621, and may be formed by metal wiring, copper sheet, etc.

FIG. 22 shows a bottom view of the bottom surface 6122B of the magnetic device 612-1B of FIG. 20 in accordance with an embodiment of the present invention. FIG. 22 shows contact pads of the magnetic device 612-1B that interface with the top surface of the substrate 611, to electrically connect to corresponding pins of the power module 700 via the substrate 611.

As shown in FIG. 22, the contact pad 661 (SW1-1) is electrically connecting the second end 625 of the turn 614-1 to the contact pad 692 through a trace 694. The contact pad 662 (SW2-1) is electrically connecting the second end 625 of the turn 614-2 to the contact pad 691 through a trace 695. The contact pad 663 (SW3-1) is electrically connecting the second end 625 of the turn 614-3 to the contact pad 691 through a trace 696. The contact pad 664 (SW4-1) is electrically connecting the second end 625 of the turn 614-4 to the contact pad 692 through a trace 697. The traces 694-697 may be formed in the substrate 611, and may be formed by metal wiring, copper sheet, etc.

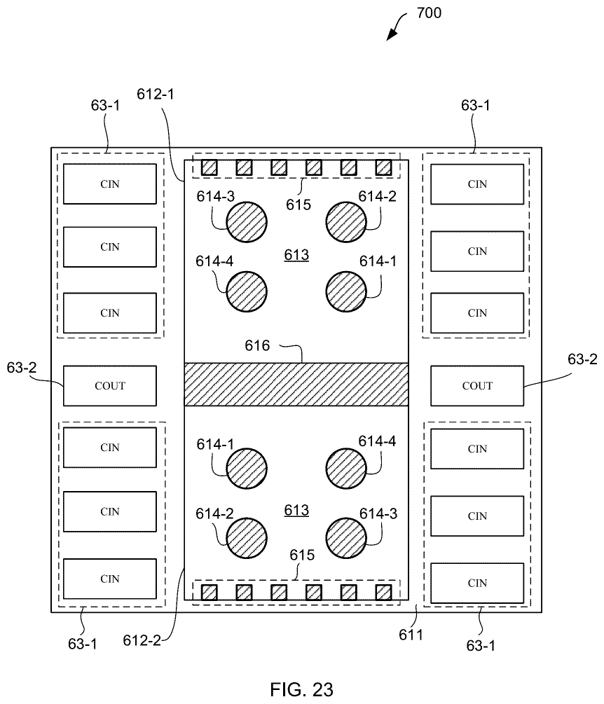

FIG. 23 shows a top view of a physical layout of the substrate 611 of the power module 700 in accordance with another embodiment of the present invention. In the example of FIG. 23, the magnetic devices 612 (i.e., 612-1, 612-2) are adhered (e.g., via thermal interface material, TIM) to a metal block 616 (e.g., a copper block) which is placed between the magnetic devices 612-1 and 612-2 for heat dissipation improvement. In one embodiment, the metal block 616 is electrically connected to the input voltage node or the power ground.

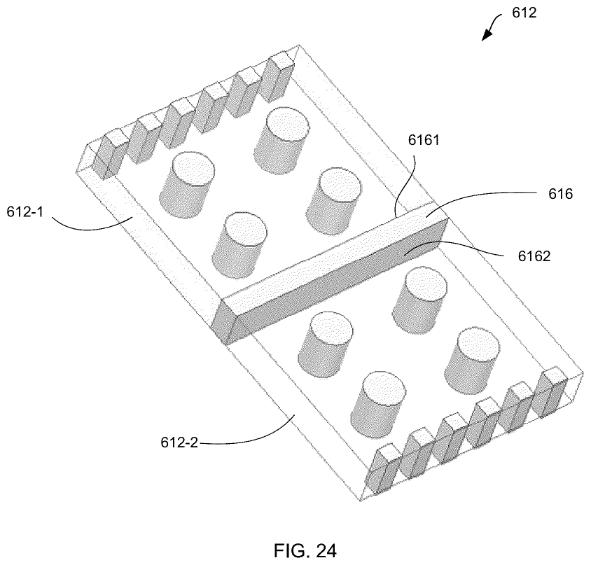

FIG. 24 shows a 3D transparent view of the magnetic device 612 in accordance with an embodiment of the present invention. In the example of FIG. 24, the magnetic device 612-1 is adhered to a first side 6161 of the metal block 616, and the magnetic device 612-2 is adhered to a second side 6162 of the metal block 616, which is opposite the first side 6161.

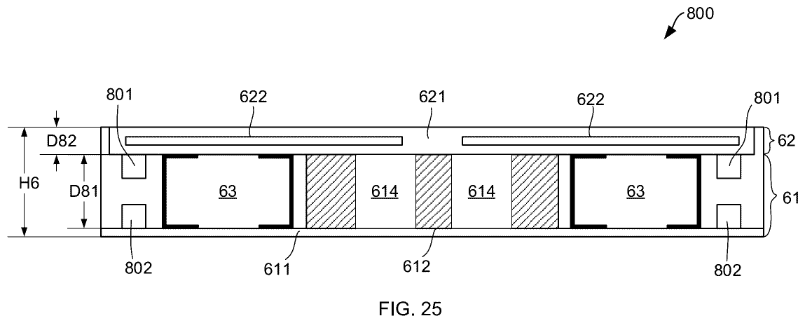

FIG. 25 shows a side cross-sectional view of a power module 800 in accordance with an embodiment of the present invention. In the example of FIG. 25, the IC dies 622 are embedded in the substrate 621. The power module 800 further has a set of capacitors 801 that are attached to the bottom surface of the substrate 621, and a set of capacitors 802 that are attached to the top surface of the substrate 611. The set of capacitors 802 face towards the set of capacitors 801 respectively. Each of the capacitors 801, 802 has a height that is lower than the height of the capacitors 63 and the magnetic device 612.

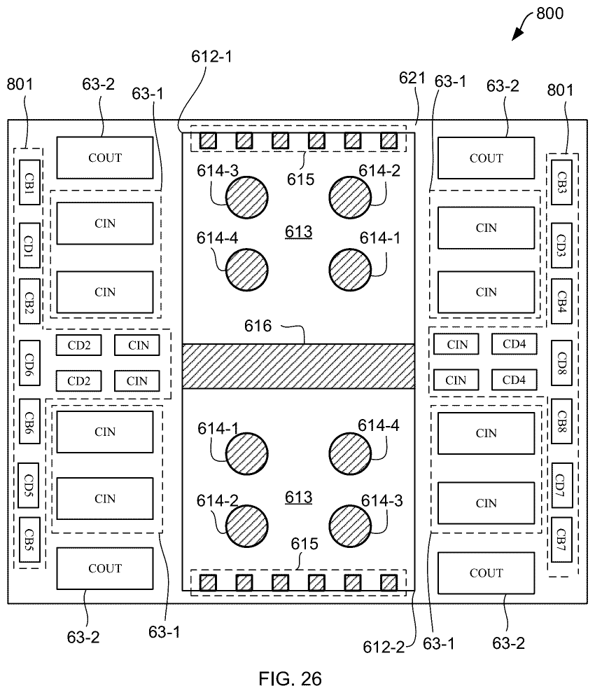

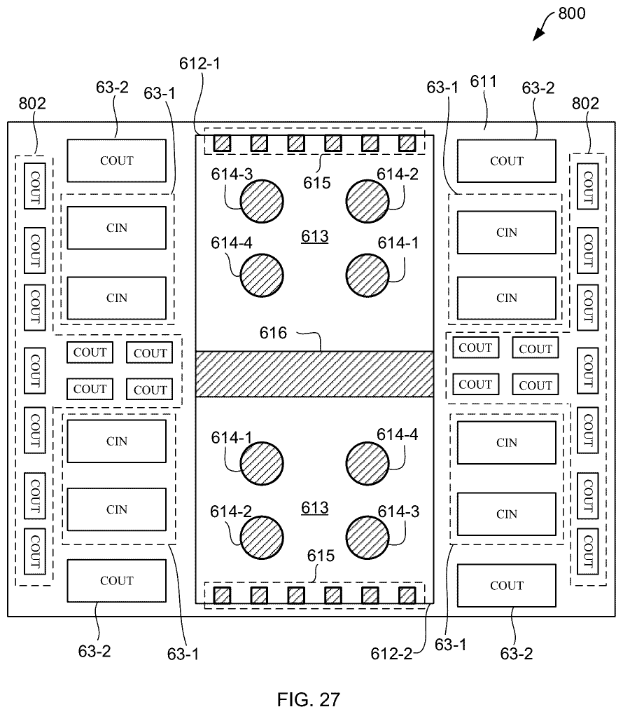

FIG. 26 shows a bottom view of a physical layout of the substrate 621 of the power module 800 in accordance with an embodiment of the present invention. In the example of FIG. 26, the collectively labeled capacitors 801 may comprise the input capacitors CIN, supply capacitors CD1-CD8, bootstrap capacitors CB1-CB8, etc. FIG. 27 shows a top view of a physical layout of the substrate 611 of the power module 800 in accordance with an embodiment of the present invention. In the example of FIG. 27, the collectively labeled capacitors 802 may comprise output capacitors COUT.

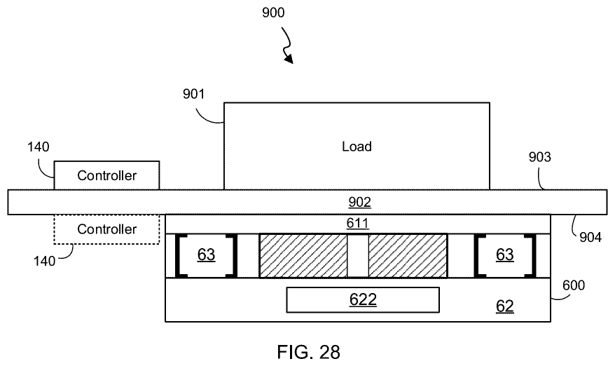

FIG. 28 shows a side view of a physical layout of a power supply system 900 in accordance with an embodiment of the present invention. FIG. 28 is not drawn to scale. In the example of FIG. 28, a module 600 provides power (e.g., an output voltage) to a load 901 (e.g., a CPU/GPU). The load 901 is disposed on a first side 903 of a motherboard 902, e.g., through associate socket and substrate. The module 600 is disposed on a second side 904 of the motherboard 902, to receive the input voltage VIN an provide the output voltage VOUT. The second side 904 is opposite to the first side 903. In one example, the power module 600 can be implemented by the power module 600A, 600B, 700 and 800 as described above. The controller 140 may be placed on the first side 903 or on the second side 904.

Low-profile power modules have been disclosed. While specific embodiments of the present invention have been provided, it is to be understood that these embodiments are for illustration purposes and not limiting. Many additional embodiments will be apparent to persons of ordinary skill in the art reading this disclosure.

What is claimed is:

1. A power module comprising:
an active layer having a first substrate and a first pair of switches; and
a passive component layer having a second substrate, an input capacitor and a magnetic device, wherein the input capacitor and the magnetic device are attached between a bottom surface of the first substrate and a top surface of the second substrate which faces toward the bottom surface of the first substrate, and the magnetic device comprises a first turn having a first end that is connected to a first switch node formed by the first pair of switches; wherein
the input capacitor has a first conducting terminal and a second conducting terminal, at least one of the first conducting terminal and the second conducting terminal is extended between the bottom surface of the first substrate and the top surface of the second substrate to provide electrical connection between the second substrate and the first substrate.

2. The power module of claim 1, wherein each of the first and second conducting terminals has a first end soldered to the bottom surface of the first substrate and a second end soldered to the top surface of the second substrate.

3. The power module of claim 1, wherein a height of the power module is at most 2 mm.

4. The power module of claim 1, wherein both the magnetic device and the input capacitor have a same height of at most 1.5 mm.

5. The power module of claim 1, wherein the passive component layer further has an output capacitor attached between a bottom surface of the first substrate and a top surface of the second substrate, wherein a first conducting terminal of the output capacitor is connected to an output voltage node, and a second conducting terminal of the output capacitor is connected to a power ground.

6. The power module of claim 1, wherein the active layer further has a second pair of switches, a third pair of switches and a fourth pair of switches, and the magnetic device further comprises:
a magnetic core;
a second turn, a third turn, and a fourth turn embedded in the magnetic core, wherein a first end of the second turn is connected to a second switch node formed by the second pair of switches, a first end of the third turn is connected to a third switch node formed by the third pair of switches, and a first end of the fourth turn is connected to a fourth switch node formed by the fourth pair of switches; and
interconnect structures capable of conducting signals between the second substrate and the first substrate.

7. The power module of claim 6, wherein the magnetic device further comprises:
a shared turn embedded in the magnetic core, wherein the shared turn is disposed in an area surrounded by the first, second, third and fourth turns;
a second end of the first turn and a second end of the fourth turn are connected to a first end of the shared turn via a first connector;
a second end of the second turn and a second end of the third turn are connected to the first end of the shared turn via a second connector; and
a second end of the shared turn is connected to an output voltage node.

8. The power module of claim 6, wherein the magnetic device has a length of at most 5 mm, and a width of at most 4 mm.

9. The power module of claim 1, wherein the passive component layer further has a second magnetic device and a metal block attached between the bottom surface of the first substrate and the top surface of the second substrate, the first magnetic device is adhered to a first side of the metal block, and the second magnetic device is adhered to a second side of the metal block which is opposite the first side of the metal block.

10. The power module of claim 1, wherein the passive component layer further has:
a first set of capacitors attached to the bottom surface of the first substrate; and
a second set of capacitors attached to the top surface of the second substrate; wherein
each of the first and second sets of capacitors has a height lower than the height of the input capacitor.

11. A power module comprising:
a first substrate;
a second substrate disposed beneath the first substrate;
a first integrated circuit (IC) die and a second IC die, wherein the first IC die has a first pair of switches and a second pair of switches, the second IC die has a third pair of switches and a fourth pair of switches;
at least one capacitor attached between a bottom surface of the first substrate and a top surface of the second substrate, wherein the at least one capacitor has a first conducting terminal and a second conducting terminal as vias to provide electrical connections between the second substrate and the first substrate respectively; and
a magnetic device attached between a bottom surface of the first substrate and a top surface of the second substrate, wherein the magnetic device comprises a first turn, a second turn, a third turn, and a fourth turn; wherein
a first end of the first turn is connected to a first switch node formed by the first pair of switches, a first end of the second turn is connected to a second switch node formed by the second pair of switches, a first end of the third turn is connected to a third switch node formed by the third pair of switches, and a first end of the fourth turn is connected to a fourth switch node formed by the fourth pair of switches.

12. The power module of claim 11, wherein the at least one capacitor comprises an input capacitor.

13. The power module of claim 11, wherein the at least one capacitor comprises an input capacitor and an output capacitor.

14. The power module of claim 11, wherein the first IC die and the second IC die are disposed on or embedded in the first substrate.

15. The power module of claim 11, wherein a height of the power module is at most 2 mm.

16. The power module of claim 11, wherein the magnetic device further comprises:
a magnetic core, wherein the first turn, the second turn, the third turn and the fourth turn are embedded in the magnetic core; and
a shared turn embedded in the magnetic core, the second end of the first turn, the second end of the second turn, the second end of the third turn, and the second end of the fourth turn are connected to an output voltage node via the shared turn.

17. A power supply system, comprising:
a motherboard having a first side and a second side, wherein a load is mounted on the first side of the motherboard; and
a power module attached to the second side of the motherboard; wherein
the power module comprises:
an active layer having a first pair of switches; and
a passive component layer having a substrate, at least one capacitor and a magnetic device, wherein the capacitor and the magnetic device are attached between a bottom surface of the active layer and a top surface of the substrate, the at least one capacitor has a first conducting terminal and a second conducting terminal as vias to provide electrical connections between the substrate and the active layer respectively.

18. The power supply system of claim 17, wherein the magnetic device and the at least one capacitor have a same height of at most 1.5 mm.

19. The power supply system of claim 17, wherein:
the active layer further comprises a second pair of switches; and
the magnetic device comprises a magnetic core, a first turn and a second turn embedded in the magnetic core; wherein
a first end of the first turn is connected to a first switch node formed by the first pair of switches, a first end of the second turn is connected to a second switch node formed by the second pair of switches, a second end of the first turn is connected to a first output voltage node of the power module, and a second end of the second turn is connected to a second output voltage node of the power module.

20. The power supply system of claim 17, wherein the substrate of the power module comprises a bottom surface that is opposite the top surface of the substrate, the bottom surface of the substrate has a plurality of pins that connect nodes of the power module to the motherboard.
